(19) United States
(12) Patent Application Publication
(10) Pub. No.: US 2026/0247595 A1
(43) Pub. Date: Aug. 20, 2026

(54) STATIC RANDOM ACCESS MEMORY DEVICE

(71) Applicant: UNITED MICROELECTRONICS CORP., Hsin-Chu City (TW)

(72) Inventors: Ting-Hsiang Huang, Tainan City (TW); Kuo-Hsing Lee, Hsinchu County (TW); Sheng-Yuan Hsueh, Tainan City (TW); Yao-Jhan Wang, Tainan City (TW); Chih-Kai Kang, Tainan City (TW); Guan-Kai Huang, Tainan City (TW)

(73) Assignee: UNITED MICROELECTRONICS CORP., Hsin-Chu City (TW)

(21) Appl. No.: 19/083,478

(22) Filed: Mar. 19, 2025

(30) Foreign Application Priority Data
Feb. 17, 2025 (TW) 114105724

(51) Int. Cl. H10B 10/00

(52) U.S. Cl. CPC H10B 10/12

(57) ABSTRACT

A static random access memory (SRAM) device includes a first fin-shaped structure and a second fin-shaped structure extending along a first direction on a substrate, a first dummy fin-shaped structure between the first fin-shaped structure and the second fin-shaped structure, a third fin-shaped structure and a fourth fin-shaped structure extending along the first direction adjacent to the second fin-shaped structure, and a second dummy fin-shaped structure between the second fin-shaped structure and the third fin-shaped structure.

### BACKGROUND OF THE INVENTION

### 1. Field of the Invention

The invention relates to a static random access memory (SRAM), and more particularly, to a layout of a SRAM.

### 2. Description of the Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer system as a cache memory.

However, as pitch of the exposure process decreases, contact plugs fabricated in current SRAM devices often have shortcomings such as pitch shrinkage and poor connection. Hence, how to enhance the current SRAM process for improving this issue has become an important task in this field.

### SUMMARY OF THE INVENTION

According to an embodiment of the present invention, a static random access memory (SRAM) device includes a first fin-shaped structure and a second fin-shaped structure extending along a first direction on a substrate, a first dummy fin-shaped structure between the first fin-shaped structure and the second fin-shaped structure, a third fin-shaped structure and a fourth fin-shaped structure extending along the first direction adjacent to the second fin-shaped structure, and a second dummy fin-shaped structure between the second fin-shaped structure and the third fin-shaped structure.

According to another aspect of the present invention, a semiconductor device includes a first fin-shaped structure and a second fin-shaped structure extending along a first direction on a substrate, a first dummy fin-shaped structure between the first fin-shaped structure and the second fin-shaped structure, a third fin-shaped structure and a fourth fin-shaped structure extending along the first direction adjacent to the second fin-shaped structure, and a second dummy fin-shaped structure between the second fin-shaped structure and the third fin-shaped structure. Preferably, the first dummy fin-shaped structure is shorter than the first fin-shaped structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a circuit diagram of a six-transistor SRAM (6T-SRAM) cell of a SRAM of the present invention.

FIG. 2 illustrates a layout of a 6T-SRAM according to an embodiment of the present invention.

FIG. 3 illustrates a method for fabricating part of the transistors from the 6T-SRAM taken along the sectional lines AA′ and BB′ of FIG. 2.

FIG. 4 illustrates a layout of a 6T-SRAM according to an embodiment of the present invention.

FIG. 5 illustrates a method for fabricating part of the transistors from the 6T-SRAM taken along the sectional lines CC′ and DD′ of FIG. 4.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

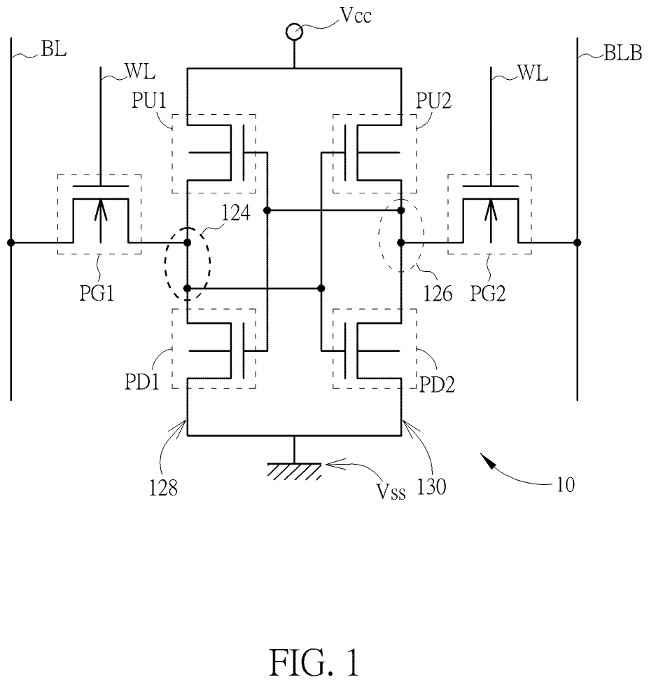

Referring to FIG. 1, FIG. 1 illustrates a circuit diagram of a six-transistor SRAM (6T-SRAM) cell of a SRAM of the present invention. As shown in FIG. 1, the SRAM device of the present invention preferably includes at least one SRAM cell, each SRAM cell including a six-transistor SRAM (6T-SRAM) cell 10.

In this embodiment, each 6T-SRAM cell 10 is composed of a first pull-up transistor PU1, a second pull-up transistor PU2, a first pull-down transistor PD1, a second pull-down transistor PD2, a first pass gate transistor PG1 and a second pass gate transistor PG2. These six transistors constitute a set of flip-flops. The first and the second pull-up transistors PU1 and PU2, and the first and the second pull-down transistors PD1 and PD2 constitute a latch that stores data in the storage nodes 24 and 26. Since the first and the second pull-up transistors PU1 and PU2 act as power load devices, they can be replaced by resistors. Under this circumstance, the static random access memory becomes a four-transistor SRAM (4T-SRAM). In this embodiment, the first and the second pull-up transistors PU1 and PU2 preferably share a source/drain region and electrically connect to a voltage source Vcc, the first and the second pull-down transistors PD1 and PD2 share a source/drain region and electrically connect to a voltage source Vss.

Preferably, the first and the second pull-up transistors PU1 and PU2 of the 6T-SRAM cell 10 are composed of p-type metal oxide semiconductor (PMOS) transistors; the first and the second pull-down transistors PD1 and PD2, and first and the second pass gate transistors PG1 and PG2 are composed of n-type metal oxide semiconductor (NMOS) transistors. The first pull-up transistor PU1 and the first pull-down transistor PD1 constitute an inverter, which further form a series circuit 128. One end of the series circuit 128 is connected to a voltage source Vcc and the other end of the series circuit 128 is connected to a voltage source Vss. Similarly, the second pull-up transistor PU2 and the second pull-down transistor PD2 constitute another inverter and a series circuit 130. One end of the series circuit 130 is connected to the voltage source Vcc and the other end of the series circuit 130 is connected to the voltage source Vss.

The storage node 124 is connected to the respective gates of the second pull-down transistor PD2 and the second pull-up transistor PU2. The storage node 124 is also connected to the drains of the first pull-down transistor PD1, the first pull-up transistor PU1, and the first pass gate transistor PG1. Similarly, the storage node 126 is connected to the respective gates of the first pull-down transistor PD1 and first the pull-up transistor PU1. The storage node 126 is also connected to the drains of the second pull-down transistor PD2, the second pull-up transistor PU2, and the second access transistor PG2. The gates of the first and the second pass gate transistors PG1 and PG2 are respectively coupled to a word line (WL), and the sources are coupled to relative bit lines BL and BLB.

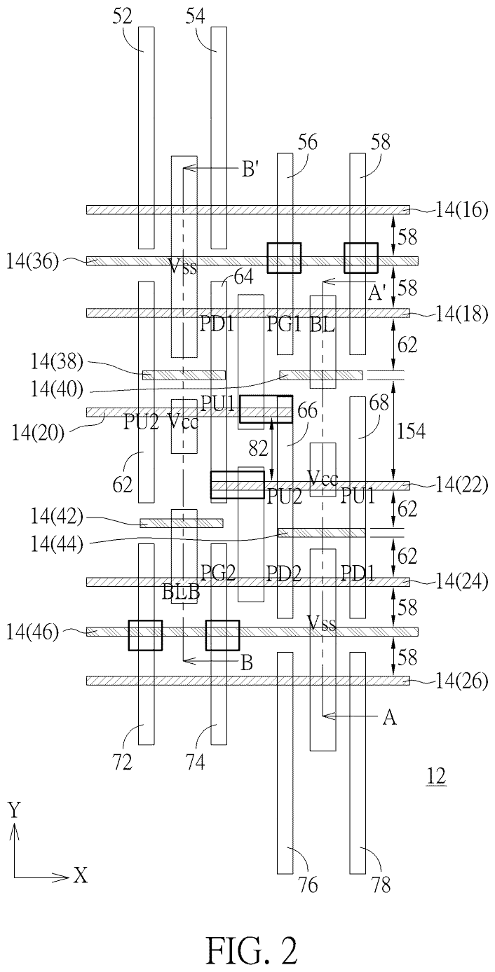

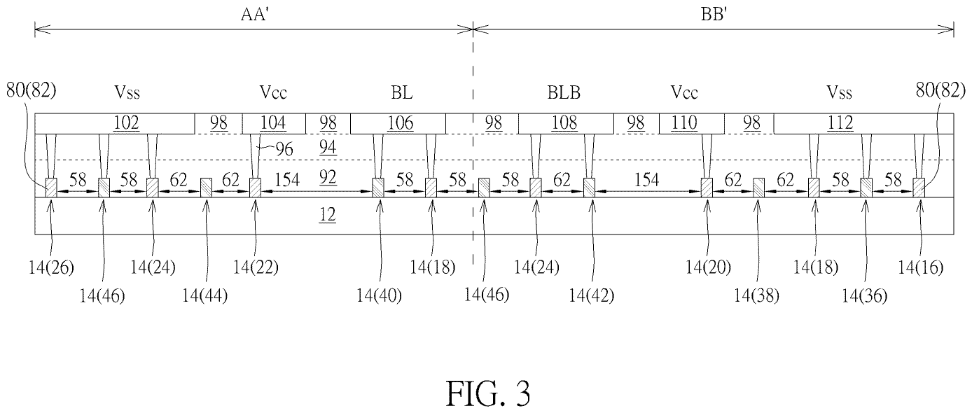

Referring to FIGS. 2-3, FIG. 2 illustrates a layout of a 6T-SRAM according to an embodiment of the present invention and FIG. 3 illustrates a method for fabricating part of the transistors from the 6T-SRAM taken along the sectional lines AA′ and BB′ of FIG. 2. As shown in FIGS. 2-3, a substrate 12, such as a silicon substrate or silicon-on-insulator (SOI) substrate is provided, a plurality of fin-shaped structures 14 are formed on the substrate 12, and the bottom of the fin-shaped structures 14 are surrounded by an insulating layer made of silicon oxide to form a shallow trench isolation (STI). In this embodiment, six of the fin-shaped structures 14 constitute active fin-shaped structures 16, 18, 20, 22, 24, 26 while the remaining six fin-shaped structures 14 are dummy fin-shaped structures 36, 38, 40, 42, 44, 46, in which the dummy fin-shaped structures 36, 38, 40, 42, 44, 46 are formed for relieving excessive space between the active fin-shaped structures 16, 18, 20, 22, 24, 26 and preventing fin-shaped structures 14 from generating cracks.

According to an embodiment of the present invention, the fin-shaped structures 14 of this embodiment could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 14 of this embodiment could also be obtained by first forming a patterned mask (not shown) on the substrate, 12, and through an etching process, the pattern of the patterned mask is transferred to the substrate 12 to form the fin-shaped structures 14. Moreover, the formation of the fin-shaped structures 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures 14. These approaches for forming fin-shaped structures 14 are all within the scope of the present invention.

Next, gate structures 52, 54, 56, 58, 62, 64, 66, 68, 72, 74, 76, 78 or dummy gates are formed on the fin-shaped structures 14 on the substrate 12, in which the transistor constituted by the gate structure 64 and active fin-shaped structure 20 in later process could be the first pull-up transistor PU1 in FIG. 1, the transistor constituted by the gate structure 64 and active fin-shaped structure 18 could be the first pull-down transistor PD1, the transistor constituted by the gate structure 56 and active fin-shaped structure 18 could be the first pass gate transistor PG1, the transistor constituted by the gate structure 66 and active fin-shaped structure 22 could be the second pull-up transistor PU2, the transistor constituted by the gate structure 66 and active fin-shaped structure 24 could be the second pull-down transistor PD2, and the transistor constituted by the gate structure 74 and active fin-shaped structure 24 could be the second pass gate transistor PG2.

In this embodiment, the formation of the gate structures 52, 54, 56, 58, 62, 64, 66, 68, 72, 74, 76, 78 could be accomplished by a gate first process, a high-k first approach from gate last process, or a high-k last approach from gate last process. Since this embodiment pertains to a high-k last approach, a gate dielectric layer or interfacial layer made of silicon oxide, a gate material layer preferably made of polysilicon, and a selective hard mask could be formed sequentially on the substrate 12, and a pattern transfer process is then conducted by using a patterned resist as mask to remove part of the gate material layer and part of the gate dielectric layer through single or multiple etching processes. After stripping the patterned resist, gate structures 52, 54, 56, 58, 62, 64, 66, 68, 72, 74, 76, 78 composed of a patterned gate dielectric layer and patterned gate material layer are formed on the substrate 12.

Next, at least a spacer is formed on sidewalls of each of the gate structures 52, 54, 56, 58, 62, 64, 66, 68, 72, 74, 76, 78, a source/drain region 80 and/or epitaxial layers 82 are formed in the fin-shaped structure 14 and/or substrate 12 adjacent to two sides of the spacer. In this embodiment, the spacer could be a single spacer or a composite spacer. For instance, the spacer could further include an offset spacer (not shown) and a main spacer (not shown), and the spacer could be selected from the group consisting of SiO₂, SiN, SiON, and SiCN. The source/drain regions 80 and epitaxial layers 82 could include different dopants or different materials depending on the type of transistor being fabricated. For instance, the source/drain regions 80 could include p-type or n-type dopants and the epitaxial layers 82 could include silicon germanium (SiGe), silicon carbide (SiC), or silicon phosphide (SiP).

In this embodiment, the four active fin-shaped structures 16, 18, 24, 26 disposed on top portion and bottom portion of FIG. 2 preferably include n-type dopants and/or epitaxial layers 82 made of silicon phosphide (SiP), the two active fin-shaped structures 20, 22 disposed in the middle portion include p-type dopants and/or epitaxial layers 82 made of silicon germanium (SiGe), the two dummy fin-shaped structures 36, 46 disposed on top and bottom portions preferably include n-type dopants and/or epitaxial layers 82 made of SiP, and the four dummy fin-shaped structures 38, 40, 42, 44 disposed in the middle portion include n-type dopants but contain no epitaxial layer whatsoever.

Next, an interlayer dielectric (ILD) layer 92 is formed on the gate structures 52, 54, 56, 58, 62, 64, 66, 68, 72, 74, 76, 78, a planarizing process such as chemical mechanical polishing (CMP) process is conducted to remove part of the ILD layer 92 so that the top surfaces of gate structures 52, 54, 56, 58, 62, 64, 66, 68, 72, 74, 76, 78 and the ILD layer 92 are coplanar.

Next, a replacement metal gate (RMG) process is conducted to transform the gate structures 52, 54, 56, 58, 62, 64, 66, 68, 72, 74, 76, 78 into metal gates. For instance, a selective dry etching or wet etching process could be conducted by using etchant including ammonium hydroxide (NH₄OH) or tetramethylammonium hydroxide (TMAH) to remove the gate material layers in the gate structures 52, 54, 56, 58, 62, 64, 66, 68, 72, 74, 76, 78 for forming recesses (not shown) in the ILD layer 92. Next, a high-k dielectric layer, a work function metal layer, and a low resistance metal layer are formed in the recesses, and a planarizing process such as CMP is conducted to remove part of low resistance metal layer, part of work function metal layer, and part of high-k dielectric layer to form metal gates. In this embodiment, the gate structures 52, 54, 56, 58, 62, 64, 66, 68, 72, 74, 76, 78 or metal gates fabricated through high-k last process of a gate last process preferably includes an interfacial layer or gate dielectric layer, a U-shaped high-k dielectric layer, a U-shaped work function metal layer, and a low resistance metal layer as the high-k dielectric layer, the work function metal layer, and the low resistance metal layer together serving as a gate electrode for each transistor or each device.

In this embodiment, the high-k dielectric layer is preferably selected from dielectric materials having dielectric constant (k value) larger than 4. For instance, the high-k dielectric layer 80 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. Preferably, the BBM layer could be selected from the group consisting of TiN and TaN, but not limited thereto.

In this embodiment, the work function metal layer is formed for tuning the work function of the later formed metal gates to be appropriate in an NMOS or a PMOS. For an NMOS transistor, the work function metal layer having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer and the low resistance metal layer, in which the material of the barrier layer may include titanium (Ti), titanium nitride (TiN), tantalum (Ta) or tantalum nitride (TaN). Furthermore, the material of the low-resistance metal layer may include copper (Cu), aluminum (Al), titanium aluminum (TiAl), cobalt tungsten phosphide (CoWP) or any combination thereof.

Next, a contact plug formation could be accomplished by first forming another ILD layer 94 on the ILD layer 92 and then conducting a pattern transfer by using a patterned mask to remove part of the ILD layer 94 directly on top of the gate structures 52, 54, 56, 58, 62, 64, 66, 68, 72, 74, 76, 78 and part of the ILD layers 92, 94 adjacent to the gate structures 52, 54, 56, 58, 62, 64, 66, 68, 72, 74, 76, 78 for forming contact holes (not showing) exposing the top surface of the gate structures 52, 54, 56, 58, 62, 64, 66, 68, 72, 74, 76, 78 and the source/drain regions 80 and/or epitaxial layers 82. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) could be deposited into the contact holes and a planarizing process such as CMP is conducted to remove part of aforementioned barrier layer and low resistance metal layer for forming contact plugs 96 electrically connecting the source/drain regions 80 and/or epitaxial layers 82.

Next, metal interconnect process from back-end-of-line (BEOL) process could be carried by first forming an inter-metal dielectric (IMD) layer 98 on the ILD layer 94, conducting one or more photo-etching process to remove part of the IMD layer 98 for forming contact holes (not shown). Next, conductive materials are deposited into the contact holes along with a planarizing process such as CMP to form metal interconnections 102, 104, 106, 108, 110, 112 connected the lower level contact plugs 96. Similar to the formation of the aforementioned contact plugs 96, the metal interconnections 102, 104, 106, 108, 110, 112 could be fabricated in the IMD layer 98 according to a single damascene or dual damascene process. For instance, each of the metal interconnections 102, 104, 106, 108, 110, 112 could include a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP). Since single damascene or dual damascene processes are well known to those skilled in the art, the details of which are not explained herein for the sake of brevity. This completes the fabrication of a semiconductor device according to an embodiment of the present invention.

As shown in FIG. 3, the fin-shaped structures 14 such as the active fin-shaped structures 16, 18, 20, 22, 24, 26 and the dummy fin-shaped structures 36, 40, 42, 46 are connected to the upper level metal interconnections through the contact plugs 96. For instance, the active fin-shaped structures 24, 26 and dummy fin-shaped structure 46 are connected to the metal interconnection 102 or voltage source Vss through the contact plugs 96, the active fin-shaped structure 22 is connected to the metal interconnection 104 or voltage source Vcc through the contact plug 96, the active fin-shaped structure 18 and dummy fin-shaped structure 40 are connected to the metal interconnection 106 or bit line BL through the contact plugs 96, the active fin-shaped structure 24 and dummy fin-shaped structure 42 are connected to the metal interconnection 108 or bit line BLB through the contact plugs 96, the active fin-shaped structure 20 is connected to the metal interconnection 110 or voltage source Vcc through contact plug 96, and the active fin-shaped structure 16, 18 and dummy fin-shaped structure 36 are connected to the metal interconnection 112 or voltage source Vss through the contact plugs 96.

Referring again to FIG. 2, FIG. 2 illustrates a layout of a 6T-SRAM according to an embodiment of the present invention. As shown in FIG. 2, the 6T-SRAM includes six active fin-shaped structures 16, 18, 20, 22, 24, 26, and six dummy fin-shaped structures 36, 38, 40, 42, 44, 46 extending along a first direction such as X-direction on the substrate 12 and gate structures 52, 54, 56, 58, 62, 64, 66, 68, 72, 74, 76, 78 extending along a second direction such as Y-direction and intersecting on top of the active fin-shaped structures 16, 18, 20, 22, 24, 26 and dummy fin-shaped structures 36, 38, 40, 42, 44, 46.

In this embodiment, the dummy fin-shaped structure 36 is disposed between the active fin-shaped structures 16 and 18, the dummy fin-shaped structures 38, 40 are disposed between the active fin-shaped structures 18 and 20, the dummy fin-shaped structures 42, 44 are disposed between the active fin-shaped structures 22 and 24, and the dummy fin-shaped structure 46 is disposed between the active fin-shaped structures 24 and 26.

Preferably, the active fin-shaped structures 16, 18, 24, 26 and dummy fin-shaped structures 36, 46 disposed on the top portion and bottom portion of the cell preferably have same length, the active fin-shaped structures 20, 22 disposed in the middle portion have same length, and the dummy fin-shaped structures 38, 40, 42, 44 disposed in the middle portion also have same length. Nevertheless, any one from the active fin-shaped structures 16, 18, 24, 26 and dummy fin-shaped structures 36, 46 and any one from the dummy fin-shaped structures 38, 40, 42, 44 have different lengths, and either of the active fin-shaped structures 20, 22 and any of the dummy fin-shaped structures 38, 40, 42, 44 have different lengths. For instance, the length of any of the dummy fin-shaped structures 38, 40, 42, 44 is preferably less than the length of any one of the active fin-shaped structures 16, 18, 24, 26 and dummy fin-shaped structures 36, 46, the length of any of the dummy fin-shaped structures 38, 40, 42, 44 is less than the length of either one of the active fin-shaped structures 20, 22, and the length of either one of the active fin-shaped structures 20, 22 is less than the length of any one of the active fin-shaped structures 16, 18, 24, 26 and dummy fin-shaped structures 36, 46.

Overall, any of the dummy fin-shaped structures 38, 40, 42, 44 has the shortest length, either one of the active fin-shaped structures 20, 22 has the medium length, and any of the active fin-shaped structures 16, 18, 24, 26 and dummy fin-shaped structures 36, 46 has the longest length, in which the shortest length could be less than half of the longest length or between 10% to 50% of the longest length and the medium length could be 40% to 70% of the longest length.

Moreover, the longer active fin-shaped structures 16, 18, 24, 26 preferably have same conductive type such as n-type dopants and/or epitaxial layers 82 made of SiP, the medium length active fin-shaped structures 20, 22 include same conductive type such as p-type dopants and/or epitaxial layers 82 made of SiGe, the longer dummy fin-shaped structures 36, 46 include same conductive type such as n-type dopants and/or epitaxial layers made of SiP, and the shortest dummy fin-shaped structures 38, 40, 42, 44 include same conductive type such as n-type dopants but do not contain any epitaxial layer.

In contrast to conventional 6T-SRAM devices without having dummy fin-shaped structures between active fin-shaped structures thereby easily resulting in cracks due to large gaps between fin-shaped structures, the present invention fills the gaps between active fin-shaped structures with the aforementioned dummy fin-shaped structures for reducing stress between fin-shaped structures and ultimately preventing fin-shaped structures from generating cracks. As shown in FIGS. 2-3, a gap or distance between active fin-shaped structures 16, 18 without the presence of dummy fin-shaped structure in conventional device is approximately 126±10% nm, a distance between the active fin-shaped structure 14 and the dummy fin-shaped structure 36 is approximately 58±10% nm after disposing the dummy fin-shaped structure 36, and a distance between the dummy fin-shaped structure 36 and the active fin-shaped structure 18 is also approximately 58±10% nm.

Similarly, a distance between the active fin-shaped structure 18 and the dummy fin-shaped structure 40 is approximately 62±10% nm, a distance between the dummy fin-shaped structure 40 and the active fin-shaped structure 22 is approximately 154±10% nm, a distance between the active fin-shaped structure 22 and the dummy fin-shaped structure 44 is approximately 62±10% nm, a distance between the dummy fin-shaped structure 44 and the active fin-shaped structure 24 is approximately 62±10% nm, a distance between the active fin-shaped structure 24 and the dummy fin-shaped structure 46 is approximately 58±10% nm, and a distance between the dummy fin-shaped structure 46 and the active fin-shaped structure 26 is approximately 58±10% nm.

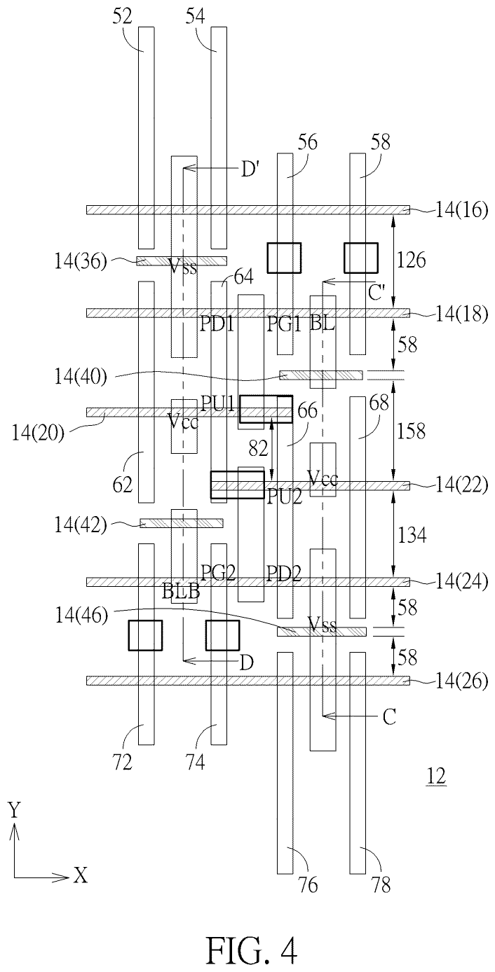

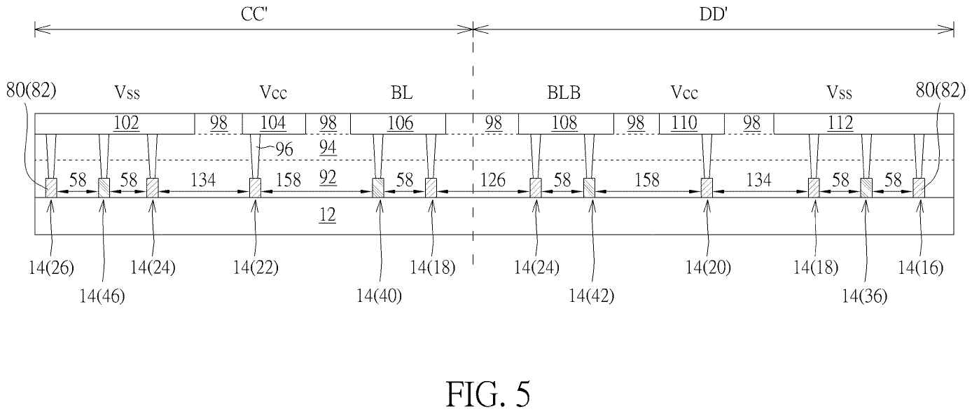

Referring to FIGS. 4-5, FIG. 4 illustrates a layout of a 6T-SRAM according to an embodiment of the present invention and FIG. 5 illustrates a method for fabricating part of the transistors from the 6T-SRAM taken along the sectional lines CC′ and DD′ of FIG. 4. For simplicity purpose, same elements from this and previous embodiments are labeled with same numbering. As shown in FIGS. 4-5, a the 6T-SRAM device preferably includes six active fin-shaped structures 16, 18, 20, 22, 24, 26, and four dummy fin-shaped structures 36, 40, 42, 46 extending along a first direction such as X-direction on the substrate 12 and gate structures 52, 54, 56, 58, 62, 64, 66, 68, 72, 74, 76, 78 extending along a second direction such as Y-direction and intersecting on top of the active fin-shaped structures 16, 18, 20, 22, 24, 26 and dummy fin-shaped structures 36, 40, 42, 46.

In this embodiment, the dummy fin-shaped structure 36 is disposed between the active fin-shaped structures 16 and 18, the dummy fin-shaped structure 40 is disposed between the active fin-shaped structures 18 and 20, the dummy fin-shaped structure 42 is disposed between the active fin-shaped structures 22 and 24, and the dummy fin-shaped structure 46 is disposed between the active fin-shaped structures 24 and 26.

In contrast to the aforementioned embodiment of having a total of six dummy fin-shaped structures or two longer and four shorter dummy fin-shaped structures 36, 38, 40, 42, 44, 46, the present embodiment only includes four shorter dummy fin-shaped structures 36, 40, 42, 46 while the four dummy fin-shaped structures 36, 40, 42, 46 having same length.

Preferably, the active fin-shaped structures 16, 18, 24, 26 disposed on the portion and bottom portion of the cell preferably have same length, the dummy fin-shaped structures 36, 46 disposed on the top portion and bottom portion of the cell have same length, the active fin-shaped structures 20, 22 disposed in the middle portion have same length, and the dummy fin-shaped structures 40, 42 disposed in the middle portion also have same length. Specifically, any one of the active fin-shaped structures 16, 18, 24, 26 and any one of the dummy fin-shaped structures 36, 40, 42, 46 have different lengths, and either of the active fin-shaped structures 20, 22 and any of the dummy fin-shaped structures 36, 40, 42, 46 have different lengths. For instance, the length of any of the dummy fin-shaped structures 36, 40, 42, 46 is preferably less than the length of either one of the active fin-shaped structures 20, 22 and the length of either one of the active fin-shaped structures 20, 22 is less than the length of any one of the active fin-shaped structures 16, 18, 24, 26.

In other words, any of the dummy fin-shaped structures 36, 40, 42, 46 has the shortest length, either one of the active fin-shaped structures 20, 22 has the medium length, and any of the active fin-shaped structures 16, 18, 24, 26 has the longest length, in which the shortest length could be less than half of the longest length or between 10% to 50% of the longest length and the medium length could be 40% to 70% of the longest length.

Moreover, the longer active fin-shaped structures 16, 18, 24, 26 preferably have same conductive type such as n-type dopants and/or epitaxial layers 82 made of SiP, the medium length active fin-shaped structures 20, 22 include same conductive type such as p-type dopants and/or epitaxial layers 82 made of SiGe, the dummy fin-shaped structures 36, 46 closer to the top portion and bottom portion include same conductive type such as n-type dopants and/or epitaxial layers made of SiP, and the dummy fin-shaped structures 40, 42 closer to the middle portion include same conductive type such as n-type dopants but do not contain any epitaxial layer.

Similar to the embodiment shown in FIG. 3, the fin-shaped structures 14 such as the active fin-shaped structures 16, 18, 20, 22, 24, 26 and the dummy fin-shaped structures 36, 40, 42, 46 shown in FIG. 5 are connected to the upper level metal interconnections through the contact plugs 96. For instance, the active fin-shaped structures 24, 26 and dummy fin-shaped structure 46 are connected to the metal interconnection 102 or voltage source Vss through the contact plugs 96, the active fin-shaped structure 22 is connected to the metal interconnection 104 or voltage source Vcc through the contact plug 96, the active fin-shaped structure 18 and dummy fin-shaped structure 40 are connected to the metal interconnection 106 or bit line BL through the contact plugs 96, the active fin-shaped structure 24 and dummy fin-shaped structure 42 are connected to the metal interconnection 108 or bit line BLB through the contact plugs 96, the active fin-shaped structure 20 is connected to the metal interconnection 110 or voltage source Vcc through contact plug 96, and the active fin-shaped structure 16, 18 and dummy fin-shaped structure 36 are connected to the metal interconnection 112 or voltage source Vss through the contact plugs 96.

Overall, the present invention discloses a layout of a 6T-SRAM device, which principally disposes six dummy fin-shaped structures 36, 38, 40, 42, 44, 46 with different lengths between active fin-shaped structures 16, 18, 20, 22, 24, 26 as shown in FIG. 2 or four dummy fin-shaped structures 36, 40, 42, 46 between active fin-shaped structures 16, 18, 20, 22, 24, 26 as shown in FIG. 4. In contrast to conventional 6T-SRAM devices having no dummy fin-shaped structures disposed between active fin-shaped structures thereby resulting in cracks due to large gaps between fin-shaped structures and stress exerted upon fin-shaped structures, the present invention fills the gaps between active fin-shaped structures with the aforementioned dummy fin-shaped structures so that stress between fin-shaped structure could be minimized and fin cracks could be prevented effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory (SRAM) device, comprising:
a first fin-shaped structure and a second fin-shaped structure extending along a first direction on a substrate;
a first dummy fin-shaped structure between the first fin-shaped structure and the second fin-shaped structure;
a third fin-shaped structure and a fourth fin-shaped structure extending along the first direction adjacent to the second fin-shaped structure; and
a second dummy fin-shaped structure between the second fin-shaped structure and the third fin-shaped structure.

2. The SRAM device of claim 1, further comprising:
a third dummy fin-shaped structure between the second fin-shaped structure and the third fin-shaped structure;
a fifth fin-shaped structure and a sixth fin-shaped structure extending along the first direction adjacent to the fourth fin-shaped structure; and
a fourth dummy fin-shaped structure and fifth dummy fin-shaped structure between the fourth fin-shaped structure and the fifth fin-shaped structure; and
a sixth dummy fin-shaped structure between the fifth fin-shaped structure and the sixth fin-shaped structure.

3. The SRAM device of claim 2, wherein the first dummy fin-shaped structure and the sixth dummy fin-shaped structure comprise same length.

4. The SRAM device of claim 2, wherein the second dummy fin-shaped structure and the third dummy fin-shaped structure comprise same length.

5. The SRAM device of claim 2, wherein the third dummy fin-shaped structure and the fourth dummy fin-shaped structure comprise same length.

6. The SRAM device of claim 2, wherein the fourth dummy fin-shaped structure and the fifth dummy fin-shaped structure comprise same length.

7. The SRAM device of claim 2, wherein the fifth dummy fin-shaped structure and the sixth dummy fin-shaped structure comprise different lengths.

8. The SRAM device of claim 1, wherein the first dummy fin-shaped structure and the second dummy fin-shaped structure comprise different lengths.

9. The SRAM device of claim 1, wherein the first fin-shaped structure and the second fin-shaped structure comprise same conductive type.

10. The SRAM device of claim 1, wherein the second fin-shaped structure and the third fin-shaped structure comprise different conductive type.

11. A static random access memory (SRAM) device, comprising:
a first fin-shaped structure and a second fin-shaped structure extending along a first direction on a substrate;
a first dummy fin-shaped structure between the first fin-shaped structure and the second fin-shaped structure, wherein the first dummy fin-shaped structure is shorter than the first fin-shaped structure;
a third fin-shaped structure and a fourth fin-shaped structure extending along the first direction adjacent to the second fin-shaped structure; and
a second dummy fin-shaped structure between the second fin-shaped structure and the third fin-shaped structure.

12. The SRAM device of claim 11, further comprising:
a fifth fin-shaped structure and a sixth fin-shaped structure extending along the first direction adjacent to the fourth fin-shaped structure; and
a third dummy fin-shaped structure between the fourth fin-shaped structure and the fifth fin-shaped structure; and
a fourth dummy fin-shaped structure between the fifth fin-shaped structure and the sixth fin-shaped structure.

13. The SRAM device of claim 12, wherein the first dummy fin-shaped structure and the fourth dummy fin-shaped structure comprise same length.

14. The SRAM device of claim 12, wherein the second dummy fin-shaped structure and the third dummy fin-shaped structure comprise same length.

15. The SRAM device of claim 12, wherein the third dummy fin-shaped structure and the fourth dummy fin-shaped structure comprise same length.

16. The SRAM device of claim 11, wherein the first dummy fin-shaped structure and the second dummy fin-shaped structure comprise same length.

17. The SRAM device of claim 11, wherein the second dummy fin-shaped structure is shorter than the third fin-shaped structure.

18. The SRAM device of claim 11, wherein the first fin-shaped structure and the second fin-shaped structure comprise same conductive type.

19. The SRAM device of claim 11, wherein the second fin-shaped structure and the third fin-shaped structure comprise different conductive type.

20. The SRAM device of claim 11, wherein the third fin-shaped structure and the fourth fin-shaped structure comprise same conductive type.
